(19) United States
(12) Patent Application Publication
(10) Pub. No.: US 2026/0235992 A1
(43) Pub. Date: Aug. 13, 2026

(54) Method and System for Optimizing a Production Process in a Technical Plant

(71) Applicant: Siemens Aktiengesellschaft, Muenchen (DE)

(72) Inventors: Ferdinand Kisslinger, Hersbruck (DE); Aziz AZMOUD, Karlsruhe (DE)

(21) Appl. No.: 19/158,837

(22) PCT Filed: Feb. 14, 2024
(86) PCT No.: PCT/EP2024/053743

§ 371 Date: Aug. 21, 2025

(51) Int. Cl. G05B 13/02; G06F 30/27

(52) U.S. Cl. CPC G05B 13/0265; G06F 30/27

(57) ABSTRACT

A method and system for optimizing a production process in a technical plant in which a technical process with at least one process step is executed, wherein a plurality of data sets of runs of a process step with values of process variables are recorded and stored in a data memory, where a process stage of the technical process to be investigated and the process variables to be investigated are initially selected, the historical data sets of the associated runs are then selected for this process stage and the selected process variables, the time series thus obtained are grouped into clusters using a machine learning method, the time series associated with the obtained clusters are displayed according to their associations, and the individual clusters are characterized and linked to metadata, and where the clusters that are characterized and linked to metadata can be used to optimize the production process.

### CROSS-REFERENCE TO RELATED APPLICATIONS

This is a U.S. national stage of application No. PCT/EP 2024/053743 filed 14 Feb. 2024. Priority is claimed on European Application No. 23158366.7 filed 23 Feb. 2023, the content of which is incorporated herein by reference in its entirety.

### BACKGROUND OF THE INVENTION

### 1. Field of the Invention

The invention relates to a computer program, a method and system for optimizing a production process in a technical plant, in which a technical process with at least one process step is executed.

### 2. Field of the Invention

Process engineering concerns the technical and economic execution of all processes in which substances or raw materials are altered in terms of their type, properties, and composition. Such a process is realized using technical plants, such as refineries, steam crackers, or other reactors, in which the technical process is primarily realized using automation technology. Technical processes are generally divided into two groups: into continuous processes and intermittent processes, known as batch processes. A complete production process, i.e., starting from specific reactants up to the finished product, can also be a mix of both process groups.

The continuous process is executed without interruptions. It is a flow process, which means there is a steady inflow or outflow of material, energy, or information. Continuous processes are preferred when processing large volumes with few product changes. One example would be a power station, which produces electricity, or a refinery, which produces fuels from crude oil.

Intermittent processes are all batch processes that run using batch control according to recipes, for example, in accordance with International Society of Automation standard 88 (ISA-88). These recipes include information about which process steps are executed consecutively or also in parallel, in order to produce a specific product with specific quality requirements. The use of material or substances frequently occurs at different points in time, i.e., in portions and on a non-linear basis in the respective subprocess. This means that the product runs through one or more reactors and remains there until the reaction has occurred and the next production step or process step can be performed. Batch processes therefore generally run in stages with at least one process step.

The process steps can therefore run on different units (physical facilities in which the process is executed) and/or with different control strategies and/or different volumes.

Sequential functional controls (SFCs) or step sequences are frequently used for this.

The term “batch” is used below as shorthand for a batch process with at least one process step. According to the ISA-88 standard, a process step is the smallest unit of a process model. In the procedural control model (cf. ISA-88), a “phase” or “function” corresponds to one process step. Such phases can run consecutively (heat the reactor, agitate within the reactor, and cool the reactor), but also parallel to each other, such as “agitate” and “keep temperature constant.” A batch process usually contains multiple process steps or phases. During production of a product, for example, each process step or each phase is usually performed numerous times (in order to produce a large quantity of a reactant, for example). The plurality of runs of data sets characterizing a process step with values or process variables are thereby recorded as a function of time and stored in a data memory.

In an ideal batch process, it is assumed that a process step or phase is executed under optimal conditions in the context of a special recipe, with a predefined control strategy and in a specific plant section or unit. It is also expected that each run of a phase (at the same point in the recipe) is the same from batch to batch. Additionally, all measurements relating to the plant show the same trend (time series of a sensor value), beginning with the start time of the phase up to the end time of the phase. This behavior can be called a “golden batch.” A golden batch thus indicates the best previously achieved production conditions in terms of quality, quantity, duration, and lowest possible volume of waste.

In a real batch process, by contrast, operations in the technical production plants are, however, influenced by a plurality of process parameters, operating parameters, production conditions, plant conditions, and settings, so that an ideal process is only approximately achieved. Factors like noise in the sensor readings, environmental conditions (e.g., external temperature), quality of the reactants, equipment defects (e.g., a valve blockage), or device failures lead to increased costs in the production process, to losses in product quality, and delays in the production process, to name but a few of the negative effects. Therefore, it is important to detect the problems in a batch production as early as possible and to identify the cause as quickly as possible, in order for the process to be corrected.

A common method of detecting problems in batch processes is to monitor process values using alert thresholds. If a threshold level for a specific process value is missed, then the operator of a plant is notified by the process control system. Configuring these threshold levels is very laborious, and multivariate deviations within the univariate threshold levels cannot be detected.

A second option for detecting problems in batch processes is to evaluate the lab measurements of the finished product. If a lab measurement is outside the quality specifications, then the process engineer can check the trend data for the corresponding batch phases. Finally, it is the process experts' task to determine the cause of a specific problem and to derive measures to resolve the problem and avoid it in the future. This approach of determining causes is very cost-intensive and requires qualified and experienced process experts. Another disadvantage is that if the problem is discovered outside the process based on a lab measurement, there is already a time delay between the phase in which the problem was discovered and the current phase of production.

This means that production problems are often only discovered too late and in retrospect.

Online monitoring of the process behavior or at least a much faster analysis of problems in batch production is achieved using a data-driven or model-based method. Physical modeling of the frequently very complex, non-linear dynamic processes is, however, very laborious and usually requires high computing capacity. Data-driven methods using artificial intelligence (AI), by contrast, allow a large volume of process data (numerous phase runs and numerous process variables) to be analyzed quickly and easily. Anomalies are easily detectable if the artificial intelligence has been trained with “good data”. However, it is not easy to interpret the large data volumes and classify them according to their context. It then becomes problematic if non-process data influences the production process, such as the ambient temperature or the quality of the starting materials. A potentially large volume of multivariate process data is generally not interpretable, which would, however, make it far easier to determine causes when problems arise in the production process. Improved analysis of the context of the process would not only facilitate error analysis but also provide an improved understanding of the production process in general.

### SUMMARY OF THE INVENTION

In view of the foregoing, it is therefore an object of the present invention to provide a data-based, simple method and system for batch processes to optimize the production process, which in a simple manner, particularly for a user of the method, improves understanding of the general process behavior and facilitates further analyses of the production process based on that understanding. Proceeding from this, it is also an object of the invention is to provide a suitable computer program, particularly a software application.

It is known that clustering can be used in data analysis to acquire knowledge and identify patterns, in order to learn more about the investigated data domain. The basic idea of the present invention is to obtain further insights and analyses related to the production process by linking a data-driven grouping of multivariate time series data of numerous runs of batch process steps with characterization using metadata, in order to improve understanding of the production process and optimize it.

These and other objects and advantages are accordingly achieved in accordance with the invention by a method for optimizing a production process in a technical plant, in which a technical process with at least one process step is executed, where a plurality of data sets of runs of a process step with values of process variables are recorded as a function of time and stored in a data memory. In accordance with the invention, a process stage of the technical process to be investigated and the process variables to be investigated are initially selected. The historical data sets of the associated runs for this process stage and the selected process variables are then selected. The time series obtained in this way are grouped into clusters using a machine learning (ML) method. The time series associated with the obtained clusters are displayed according to their associations, and the individual clusters are characterized and linked to metadata. The clusters that are characterized and linked to metadata can be used to optimize the production process.

There are various advantages of the method in accordance with the invention. The biggest advantage of the inventive method is that a potentially large volume of multivariate process data is reduced to groups or clusters of phase runs with similar behavior. This is performed automatically using an ML algorithm. A user of the method in accordance with the invention has the option of investigating the clusters found with the ML model using various representations and by linking to metadata. The linking can be effected manually (by users themselves) or automatically through a suitable algorithm. Advantageously, the length of the investigation, i.e., the period of time of the process to be investigated (the process stage) can be freely selected. It is not strictly necessary for the process stage being investigated to coincide with a process step or a phase. The selected process stage can also extend across phases. In general, a process stage comprises a fixed time period of the technical process with a defined start and end time.

The clusters can thereby be displayed in a user interface in a particularly advantageous way, for example, as ribbons. A user has the option of characterizing and contextualizing the clusters with comments or various categorizations. The clusters can be characterized manually, but also automatically using a suitable algorithm. Any metadata can be stored, such as causes of problems that have occurred, instructions for solutions/corrections, or an evaluation of how critical process behavior reflected in the behavior of the cluster is in the investigated process stage. The user also gains information about which historical phase runs were grouped in a cluster and how the behavior of the cluster has developed over time. This gives the user a deeper insight into the process behavior, particularly if a great many phase runs are grouped into one cluster. If a characterized cluster is a process step, for example, which produces good product quality (e.g., a synthetic substance with high purity), then the configured control and operating parameters of this process stage can be reproduced to optimize production.

In a particularly advantageous embodiment of the method in accordance with the invention, a time series of a process stage can be selected for a new data set of the batch process (multivariate time series data of the process variables) and can be checked to determine the cluster to which the data set to be investigated belongs. This does not need to be a current data set. Investigation of historical data sets is also possible. “New” in this context means that the data set has not yet been included in a clustering under the previously used ML method.

In the presently contemplated embodiment, a new data set of a process stage is checked for at least one process variable using a metric adapted to the cluster method, in order to determine whether or how well the values of the data set can be assigned to a previously characterized cluster. After the data set has been assigned to one or more clusters, at least some of the metadata previously stored with the cluster is displayed for the user. This can be used not only to optimize the production process, but also to monitor the production process. A user can utilize the stored metadata to evaluate or correct the current process in particular. If the new data of the batch phase matches a cluster, then a user can be notified that a specific process behavior has been found, for example. When historical data is analyzed, the user can be provided with a summary of the process behavior found in connection with the cluster. Assignment to a cluster of phase runs also has the advantage that the cluster takes into account the variation of measurement data for this process behavior as well. The probability of a successful assignment can thus increase, compared to a method in which similarity is determined in pairs. As a result, statements about current process behavior can advantageously be made very quickly in the case of automated assignment.

In another advantageous embodiment, the metric for assigning the new data set to a cluster is calculated using an adaptation factor, where the width and mean value of an observed cluster ribbon are initially determined. A scaled deviation (=distance to the mean value of the cluster ribbon scaled by the corresponding bandwidth) is then determined per time stamp of the new data set, and a quantity of the scaled deviations and strength of deviation are determined for all time stamps of the new data set, which exceed a specific size of the scaled deviations. The various durations of the time series of the cluster are also considered in comparison to the duration of the new data set. The factor should be 100 %, if all values of the process variables of the data set reside within the cluster ribbon for all time stamps. The assignment of a new data set to a cluster can be quantified advantageously using the adaptation factor. The quality and accuracy of the process monitoring can be increased significantly in this manner.

In another embodiment, anomalies are advantageously filtered by evening out the scaled deviations along the time axis. This would be feasible using a median filter, for example, which moves along the time axis and takes a plurality of measured values into account rather than individual values, which is particularly convenient for sensors with high noise.

The method in accordance with the invention of assigning a new data set to at least one cluster with its disclosed embodiment can advantageously be used during ongoing operation of a technical plant and can also be performed in real time. While the cluster analysis method of selecting specific runs and process variables, clustering and characterizing is only partially suitable as an online method during ongoing operation, new data sets can be assigned much more quickly to the previously saved clusters, as the clusters are already present and the adaptation factor can be calculated automatically. Once the user has the time series data of at least one process variable of a process stage, it is possible to check whether the time series can be assigned to a cluster. In this way, the user very quickly gains an insight into process behavior. The metadata of the found cluster can be used to influence ongoing operation if required, by modifying control parameters or target values or adapting process variables (such as temperature in a reactor, pressure, or fill level).

In a particularly advantageous embodiment, the assignment of a new data set to a cluster during ongoing operation can be initiated or triggered if a specific condition is met. It is particularly advantageous to begin cluster assignment if the duration of the new data set corresponds to at least a predefined fraction of the median of the durations of the time series of the cluster. A user can thus stipulate when an analysis is useful. Alternatively, the trigger can also be set automatically. If the new data of the batch phase matches a cluster, and a user is repeatedly notified that a specific process behavior has been found, then the trigger can prevent a user receiving too many notifications. In summary, the trigger function allows for more flexible handling of cluster assignment.

In other advantageous embodiments, the process stage can be selected using a logic or on a data-driven basis, in particular using data from the production process, e.g., using time series segmentation. The logic can, for example, be based on the realization of the batch process in an automation system or a control. Alternatively, particular process steps (e.g., “A cluster analysis should only be performed for heating a reactor”) or critical periods of time in the course of a process, for example, can be specified by a user or an algorithm. This advantageously allows for flexible cluster analysis adapted to the respective situation and plant.

The plurality of time series of process runs are grouped into clusters using a machine learning method. This means that the clusters or groups are not formed based on predefined common features as with classification, but rather that the groups or clusters are collated based on a spatial distance metric of vectors (here the time series data). There are various methods for determining this distance, such as the Euclidean or Minkowski metric. Additionally, it is also noted that this application involves multivariate time series of different lengths. Accordingly, “dynamic time warping” methods can also be used. The use of distance metrics for time series data for the clustering represents the most precise option for comparison, but this does also lead to high sensitivity, for example, in relation to the noise of the measured process values. There are instances in which it is advantageous to increase the robustness of the method, e.g., with respect to the noise of the measured values. In these instances, it is advantageous to use more robust features. This can be an embodiment involving statistical features, such as mean value, standard deviation, or skew of the sensor data (process variables). Data-driven features of the time series are calculated in another embodiment, e.g., the latent representation of an autoencoder that has been trained on the data of the process stage. Both embodiments are likewise highly robust and efficient.

The objects and advantages are likewise achieved in accordance with the invention by a use of the method with all its embodiments, as explained above, for labeling groups of data sets, particularly time series data. If clustered data consisting of time series data is already available, a user can give this so-called labels by characterizing with metadata. In this way, a monitored method could advantageously be derived from the unmonitored method of machine learning. In addition, the individual clusters, which are evaluated and characterized individually and therefore correspond to labeled data sets, would be available for a classification method.

Other data analyses are possible on the basis of this. Another advantage is that the metadata can be used as labels for training the machine learning algorithm, e.g., to balance the usually high number of “good” runs with the low number of errors or “bad” runs.

The objects and advantages are further achieved in accordance with the invention by a use of the method with all its embodiments, as explained above, for causal analysis of problems occurring in the production process of a technical plant. This is a particularly simple but very efficient type of causal analysis, if the metadata is of high quality. If the metadata linked to a cluster comprises detailed and meticulous documentation of the historical process behavior by an expert, then this knowledge can be very valuable in identifying and resolving problems.

The objects and advantages are further achieved in accordance with the invention by a system for optimizing the production process in a technical plant. The term “system” can refer both to a hardware system, such as a computer system consisting of servers, networks, and memory units, and to a software system, such as software architecture or a larger software program. A mix of hardware and software is also conceivable, for example, an IT infrastructure such as a cloud structure with its services. Components of such an infrastructure are usually servers, memories, networks, databases, software applications and services, data directories, and data management systems. Virtual servers in particular are part of a system like this.

The system in accordance with the invention can also be part of a computer system that is physically separate from the location of the technical plant. The connected external system then advantageously has components that are designed to execute the method in accordance with disclosed embodiments of the invention. Coupling to a cloud infrastructure can be effected in this way, for example, which also increases the flexibility of the overall solution.

Local implementation on computer systems of the technical plant can also be advantageous. Implementation is particularly suitable for security-relevant processes, e.g., on a server of the process control system or on premise, i.e., within a technical plant.

The method in accordance with disclosed embodiments of the invention is thus preferably implemented in software or in a combination of software and hardware, so that the invention also relates to a computer program, particularly a software application, with program code instructions executable on a computer to implement the method. Such a computer program can, as described above, be loaded on a memory of a server, e.g., of a process control system, so that the operation of the technical plant is monitored automatically or, for cloud-based monitoring of a technical plant, the computer program can be held on or be loadable on a memory of a remote service computer.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The invention is described in more detail and explained below with reference to the figures and with reference to an exemplary embodiment, in which:

FIG. 1 is an exemplary graphical plot of data-driven groupings of multivariate time-series data of runs of a batch process stage;

FIG. 2 is a schematic representation for illustrating the method of cluster analysis in accordance with the invention;

FIG. 3 is a schematic representation for illustrating the method of assigning a data set of a time series to existing clusters in accordance with the invention;

FIG. 4 is a schematic illustration of an exemplary a system suitable for executing the method in accordance with the invention; and

FIG. 5 is a flowchart of the method in accordance with the invention.

### DETAILED DESCRIPTION OF THE EXEMPLARY EMBODIMENTS

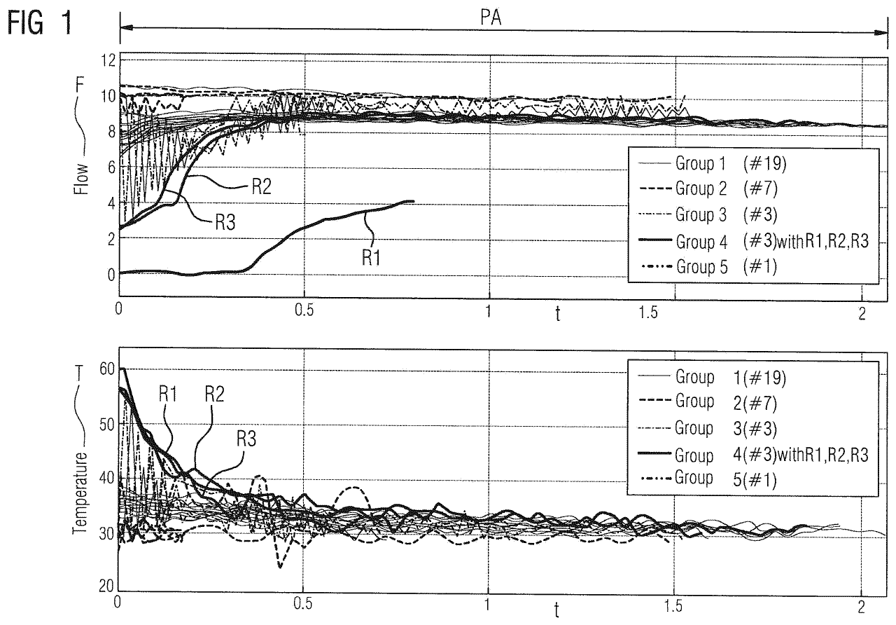

FIG. 1 shows an exemplary representation, in accordance with a first embodiment of the invention, of the result for two process variables of grouping time series of a plurality of data sets of runs of a batch process stage. The time series are trends or time series of different runs of the displayed process variables flow F and temperature T, whose values are plotted against the time t. The displayed time window corresponds here to a process stage PA. In each instance, 5 groups or clusters (Group 1 to 5) are represented per process variable. The time series associated with the obtained clusters are characterized by line type according to their associations in this exemplary embodiment. The visualization of cluster associations can be freely chosen. Group 1 comprises the time series data of 19 runs of the corresponding process variables in each instance. Group 2 comprises the time series of 7 runs, Group 3 comprises the time series of 3 runs, Group 4 comprises the time series of 3 runs, and Group 5 comprises an individual time series of a run (which is not identifiable, however). The data sets for the individual runs R1, R2, and R3 are labeled for Group 4 in FIG. 1 for the displayed process variables T and F. The individual clusters are usually stored independently of each other.

The term “time series” is used in this context to mean that data is recorded discretely (with specific time stamps) at finite chronological intervals, rather than continuously. In order to monitor the operation of a technical plant, a plurality of data sets of process variables, which characterize the operation of the plant, are recorded as a function of time t and stored in a data memory (frequently an archive). Consequently, “as a function of time” means here either at specific individual points in time with time stamps, or with a sampling rate at regular intervals, or even approximately continuously. In the data sets of a run R1, n values of the respective process variables are thus included with the respective time stamps, where n represents any natural number. Process variables are generally recorded using sensors. Examples of process variables are temperature T, pressure P, flow F, fill level L, density or gas concentration of a medium.

The starting point of each process step or phase is marked with t=0. Comparing the multivariate data of the numerous runs in FIG. 1, it is evident that there are differences in the durations of the time series. The different durations can be taken into account both with the clustering method and when assigning a new data set of a run to individual clusters.

The term “process stage” is used in accordance with the invention to mean any period of time of the batch process. A process stage can correspond to a length of a batch phase but can also just constitute a fraction thereof. These periods of time can also extend across phases or even comprise multiple phases. A process stage therefore corresponds to a freely selectable period of time of the technical process with a fixed start time to and a fixed end time tend. It should be definable and repeatable.

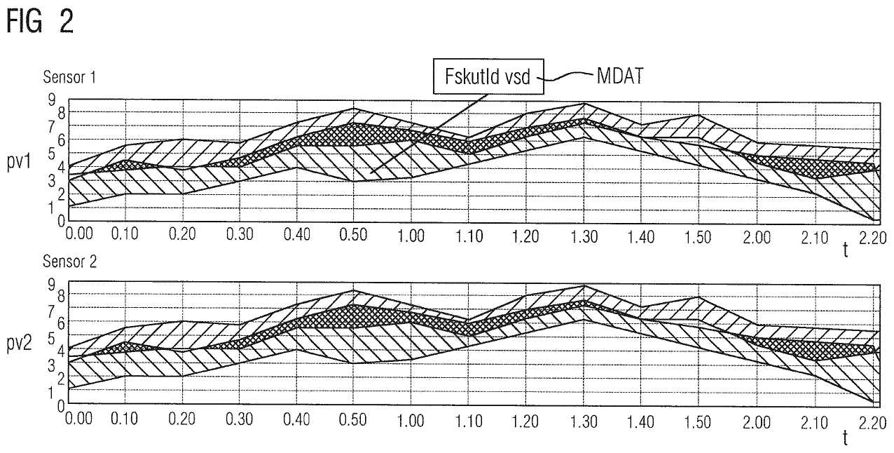

A user now has the option of investigating the obtained clusters using various representations or displays and by linking with metadata. FIG. 2, for example, shows a schematic representation of a visualization of the individual groups or clusters using ribbons. The time series associated with the obtained clusters are therefore grouped into cluster ribbons according to their associations. The cluster ribbons for 2 process variables pv1 and pv2 are shown, which were each recorded with corresponding sensors. A ribbon has been chosen in this exemplary embodiment such that all minimums and maximums of the values for the cluster process variables per time stamp define the upper and lower limit of the ribbon. A user now has the option of characterizing or contextualizing the clusters, including with comments or various categorizations. For example, the following metadata MDAT can be stored with a cluster:
Causes of problems
An assessment of how critical the process behavior is that is associated with the cluster
Instructions for solutions/corrections
Points of contact

Clusters are generally characterized with metadata manually via an entry by the user. However, the metadata can also be linked automatically if, for example, specific features of the clusters trigger an automatic command for information to be linked to the cluster.

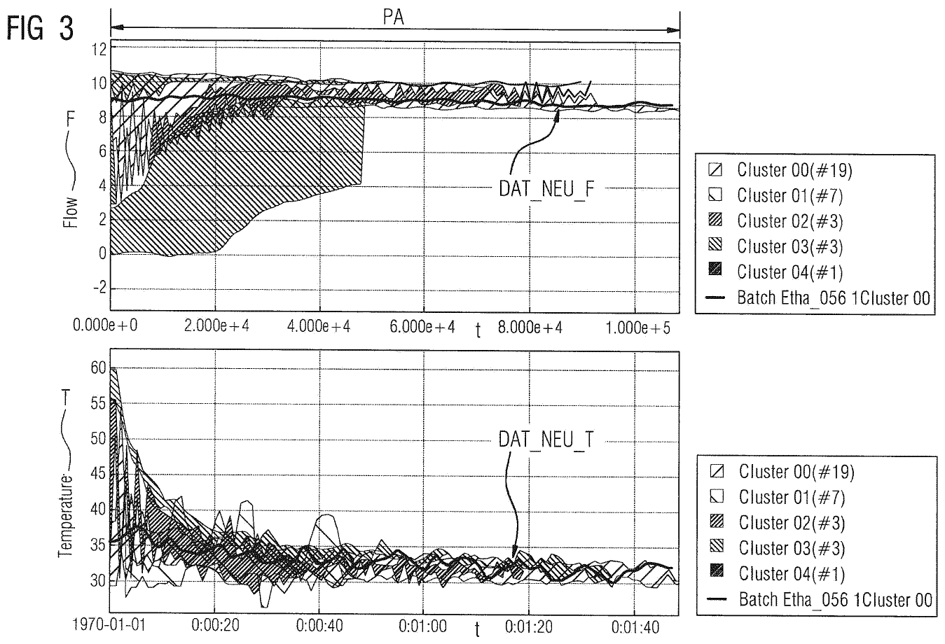

A user can select individual clusters from one or more cluster analyses, in order to use these for monitoring new online data or for applying to other historical data. This embodiment of the method in accordance with the invention becomes evident from FIG. 3.

The groups or clusters from FIG. 1 are displayed as ribbons in FIG. 3. The displayed graphs are shown in the dashboard of a software application by way of example. During ongoing operation of a technical plant, a user now obtains new data sets DAT_NEU_F and DAT_NEU_T in each instance of runs of the represented process variables flow F and temperature T for the previously selected process stage PA. The user can now initiate an assignment of the new data set per process variable to one of the shown clusters. It would also be conceivable for an assignment to be made to any cluster previously saved for the corresponding process variable.

The assignment algorithm is based on a metric adapted for the cluster method and checks whether or how well the values of the new data set can be assigned to a previously characterized cluster. After the data set has been assigned to one or more clusters, at least some of the metadata previously stored with the cluster can be displayed and can also be used to monitor the production process. The advantage of the contextualization is that the user can be offered a suggested optimization/solution directly if a match is found with a corresponding cluster. As the clusters and the associated metadata can be monitored and maintained independently of the cluster analysis and selectively (i.e., only including some of the clusters), the method offers the option of only retaining the saved clusters (with the associated metadata if applicable) that are relevant for the future. For example, special cases of phase runs or unusual behavior that has occurred in the past for known reasons (e.g., the reactor had to be operated in May with a replacement pump that had different dimensions) can thus be excluded. This can also reduce the number of pointless notifications.

In order for such a robust cause analysis to be performed, a plant operator or process engineer can be shown diverse information for the new data set combined with the assigned cluster. Moreover, the precise content of the metadata can be configured for each application. Finally, it is noted that the metadata can come from different information sources and access to these can be effected manually or automatically.

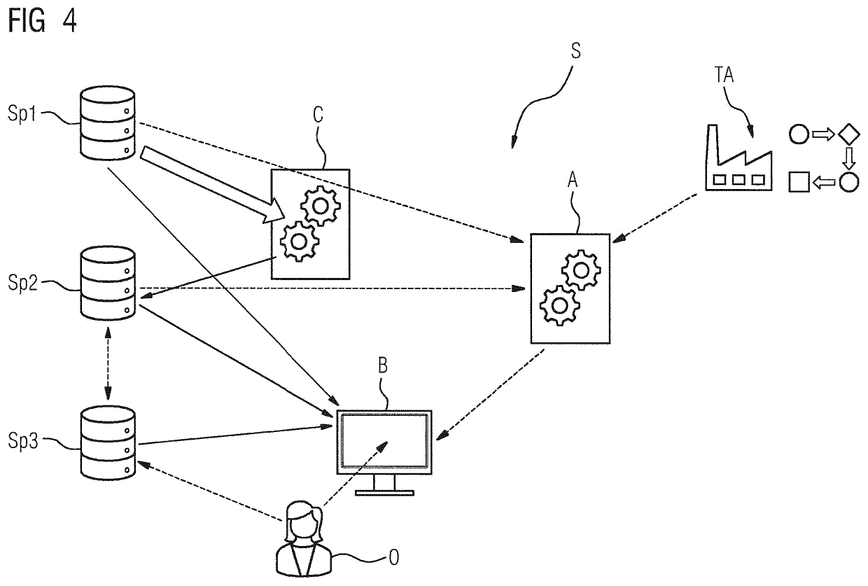

Reference is made to FIG. 4 in this context. This shows an exemplary embodiment of a system S, which is configured such that it executes the method in accordance with the invention. The system S comprises three units for storing data in this exemplary embodiment. At least one data memory should be present depending on the embodiment. When there is more than one data memory, the data to be stored can be distributed in any manner. In this exemplary embodiment, data memory Sp1 contains a plurality of historical data sets with the multivariate trends of the phase runs. All historical data sets, data sets containing values of a plurality of process variables with corresponding time stamps, can be used for the ML model for clustering.

For clustering the many data sets of runs of the individual process variables, which is effected in processing unit C in this exemplary embodiment, processing unit C is connected to the memory unit Sp1. In a particularly advantageous embodiment, the processing unit C is part of a superordinate evaluation unit (not shown). It is conceivable in each instance to have different units or just one unit in the form of a server, on which an application is implemented with all functions of calculation and evaluation. The evaluation unit and/or the processing unit C can also be connected to a control system of a technical plant TA or to a computer of a technical plant section, on which a technical process is executed with at least one process step, via a communication interface, via which (e.g., on request) the multivariate data sets of the phase runs are transmitted. An automation system or a process control system controls, regulates, and/or monitors a technical process in the technical plant TA. The process control system is connected to a plurality of field devices (not shown) for this purpose. Measuring transmitters and sensors are used to record process variables, such as temperature T, pressure P, flow volume F, fill level L, density or gas concentration of a medium.

The clusters identified using processing unit C, as well as other analysis results, such as cluster ribbons and/or the associated features of the individual clusters (e.g., mean values, standard deviations, or autocorrelations), are stored in another memory unit Sp2 in the exemplary embodiment illustrated in FIG. 4. The clusters in their respective graphical design can be displayed on the graphical user interface of a display unit B for visualization. A system operator 4 user O or a process expert can characterize the clusters at this point, by entering comments or metadata sets in an input field of the user interface. As shown in this embodiment, the metadata can be stored in another memory Sp3, which is automatically linked to Sp2, the memory for the cluster ribbons. An embodiment of the system is also conceivable in which the memory is organized or classified for the metadata with respect to the phases, the batches of the equipment of the plant, etc. An individual memory unit for the metadata is also conceivable in correlation with the clusters or cluster ribbons.

If the system S receives a data set from the technical plant TA (for example, during ongoing operation of the plant), this data set, which contains the time series data of a process stage to be investigated, is transmitted to a unit A, in which the new data set's associations with the clusters already identified in unit C are checked. Alternatively, the unit A can also receive a historical data set from the memory unit Sp1 with the historical multivariate data. The units and memories are communicatively connected for this purpose. After the cluster association check in unit A, a message or notification is sent to the user O, stating whether and to which cluster the new data set should be assigned. The message is displayed on the graphical user interface of the display unit B.

The display and control unit B can also be connectable directly to the system or, depending on the implementation, can be connected to the system via a data bus, for example. In a particularly advantageous embodiment, the display unit is part of the system S.

The clusters associated with a data set are displayed on the user interface of the display and control unit B. The associated metadata is also displayed. A process expert can now check the result and determine the cause of problems. Thus, a system user O has the option of adding comments or metadata sets for the currently analyzed clusters in an input field of the user interface during the cause analysis. By storing this metadata, the system becomes more intelligent over time and can be considered as an interactive self-learning system.

The system S for executing the method in accordance with the invention can also be realized in a client-server architecture, for example. The server with its data memories hereby provides certain services like the system in accordance with the invention, for processing a precisely defined task (here the calculation of the clusters and the assignment of new data sets to the existing clusters). The client (here unit B) is able to request and use the corresponding services from the server. Typical servers are web servers for providing website content, database servers for storing data, or application servers for providing programs. Interaction between the server and client is effected via suitable communication protocols such as http or jdbc. Another option is the use of the method as an application in a cloud environment (e.g., the Siemens MindSphere), where one or more servers host the system in accordance with the invention in the cloud. Alternatively, the system can be implemented directly in the technical plant as an on-premise solution, so that a local connection to databases and computers is possible on the control system level.

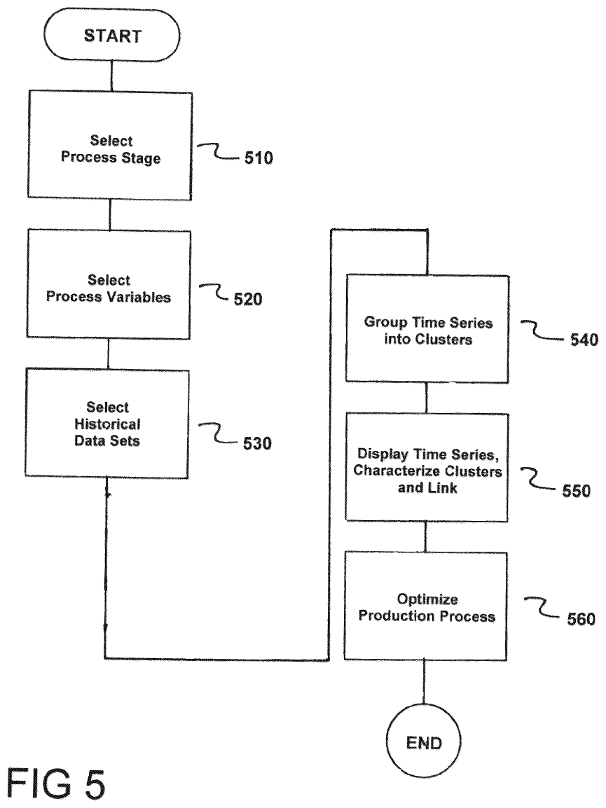

FIG. 5 is a flowchart of the method for optimizing a production process in a technical plant, in which a technical process with at least one process step is executed, where a plurality of data sets of runs R1, R2, . . . , RM of a process step with values of process variables are recorded as a function of time and stored in a data memory.

The method comprises selecting a process stage PA of the technical process to be investigated, as indicated in step 510.

Next, the process variables to be investigated for this process stage PA are selected, as indicated in step 520.

Next, historical data sets of the associated runs for this process stage PA and the selected process variables are selected, as indicated in step 530.

Next, the obtained time series are grouped into clusters via a machine learning method, as indicated in step 540.

Next, the time series associated with the obtained clusters according to their associations are displayed, individual clusters are characterized and the characterized individual clusters are linked to metadata, as indicated in step 550.

The clusters that are characterized and linked to metadata are now utilized to optimizes the production process, as indicated in step 560.

Thus, while there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements and/or method steps that perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1-13. (canceled)

14. A method for optimizing a production process in a technical plant, in which a technical process with at least one process step is executed, a plurality of data sets of runs of a process step with values of process variables being recorded as a function of time and stored in a data memory, the method comprising:
selecting a process stage of the technical process to be investigated;
selecting the process variables to be investigated for this process stage;
selecting historical data sets of the associated runs for this process stage and the selected process variables;
grouping obtained time series into clusters via a machine learning method;
displaying the time series associated with the obtained clusters according to their associations, and characterizing individual clusters and linking said characterized individual clusters to metadata; and
optimizing the production process utilizing the clusters which are characterized and linked to metadata.

15. The method as claimed in claim 14, wherein a new data set of a process stage is checked for at least one process variable utilizing a metric adapted to the cluster method to determine whether or how well values of the data set can be assigned to a previously characterized cluster; and
wherein at least some of the metadata previously stored with the cluster is displayable for the user and be usable to monitor the production process after the data set has been assigned to one or more clusters.

16. The method as claimed in claim 15, wherein a metric for assigning the new data set to a cluster is calculated utilizing an adaptation factor;
wherein initially a width and mean value of an observed cluster ribbon are determined, a scaled deviation is determined per time stamp of the new data set, the quantity and strength of deviation is determined for all time stamps of the new data set, which exceed a specific size of the scaled deviations; and
wherein various durations of the time series of the cluster are considered in comparison to the duration of the new data set.

17. The method as claimed in claim 16, wherein the scaled deviation comprises a distance to a mean value of a cluster ribbon scaled by a corresponding bandwidth.

18. The method as claimed in claim 16, wherein anomalies are filtered by evening out the scaled deviations along the time axis.

19. The method as claimed in claim 15, wherein the method is optionally performable in real time during ongoing operation of the technical plant.

20. The method as claimed in claim 15, wherein the assignment of a new data set to a cluster is triggered during ongoing operation if the duration of the new data set corresponds to at least a predefined fraction of a median of durations of the time series of the cluster.

21. The method as claimed in claim 14, wherein the process stage is selected in accordance with a logic or based on a data-driven basis utilizing data from the production process.

22. The method as claimed in claim 14, wherein clustering is effected in accordance with statistical or data-driven calculated features of the time series or based on the time series themselves.

23. The method as claimed in claim 14, wherein the method is utilized to label groups of data sets comprising time series data.

24. The method as claimed in claim 14, wherein the method is utilized to perform causal analysis of problems occurring in the production process in a technical plant.

25. A system for optimizing a production process in a technical plant in which a technical process with at least one process step is executed, comprising at least:
at least one memory unit for storing at least historical data sets with values of process variables recorded as a function of time, which characterize one of (i) a run of a process step, (ii) metadata pertaining to the process and (iii) cluster ribbons and features related to identified clusters;
a processor configured at least to identify clusters utilizing a machine learning model and which is connected to the at least one memory unit; and
a unit for displaying the identified clusters and other analysis results and for characterizing the clusters with corresponding metadata;
wherein the processor is configured to:
select a process stage of the technical process to be investigated is selected;
select the process variables to be investigated for this process stage;
select historical data sets of the associated runs for this process stage and the selected process variables;
group obtained time series into clusters via a machine learning method;
characterize individual clusters and link said characterized individual clusters to metadata;
optimize the production process utilizing the clusters which are characterized and linked to metadata; and
wherein the unit displays the time series associated with the obtained clusters according to their associations.

26. The system as claimed in claim 25, further comprising:
a unit for checking whether a new data set of a process stage belongs to a previously identified cluster.

27. A computer program comprising a software application including program code instructions executable by a computer for implementing the method as claimed in claim 14 when the computer program is executed on a computer.
